(19) United States
(12) Patent Application Publication
(10) Pub. No.: US 2010/0328187 A1
(43) Pub. Date: Dec. 30, 2010

(54) Method for producing an antenna system

(75) Inventors: Marc Husemann, Hamburg (DE); Frank Hannemann, Hamburg (DE); Matthias Koop, Norderstedt (DE)

Correspondence Address: Hildebrand, Christa;Norris McLaughlin & Marcus PA, 875 Third Avenue, 8th Floor, New York, NY, 10022, US

(73) Assignee: tesa SE, Hamburg (DE)

(21) Appl. No.: 12/808,921

(22) PCT Filed: Dec. 12, 2008
(86) PCT No.: PCT/EP2008/067457

§ 371 Date: Sep. 3, 2010

(30) Foreign Application Priority Data
Dec. 21, 2007 (DE) 10 2007 063 020.6

(51) Int. Cl. H01Q 1/12; H05K 3/00; B32B 7/12

(52) U.S. Cl. 343/878; 29/600; 428/346; 428/355 R

(57) ABSTRACT

The invention discloses a method for producing an antenna system having at least one metal antenna unit and at least one carrier unit, wherein said antenna unit is connected in a first connection step to a heat-activated surface element, which can be glued, and the heat-activated surface element, which can be glued, is connected in a second connection step to the carrier unit, wherein the heating of said surface element in the second connection step occurs through said antenna unit. Furthermore, a surface element which is particularly suitable for this method and the products obtained therefrom are disclosed.

The invention relates to a method for producing an antenna system comprising at least one metallic antenna unit and at least one carrier unit, said method comprising contacting the antenna unit with a first side face of an adhesive system, in a first joining step, joining the antenna unit to the first side face of the adhesive system to form an antenna element, contacting the resulting antenna element on the second side face of the adhesive system with a carrier unit, and, in a second joining step, durably joining the carrier unit to the second side face of the adhesive system of the antenna element. The invention further relates to a heat-activatedly bondable sheetlike element for durably joining a metallic antenna unit to a carrier unit, said sheetlike element comprising at least one heat-activatedly bonding adhesive, and relates, moreover, to an antenna element having a metallic antenna unit and a sheetlike element of this kind, to an antenna system having an antenna element of this kind and a carrier unit, and to the use of the heat-activatedly bondable sheetlike element for durably joining a metallic antenna unit and a carrier unit.

As a consequence of the increasing propagation of small electronic devices, many technical devices have been adapted to communicate with one another by means of wireless signal transmission—examples of this are mobile telephones, navigation devices, electronic notebooks (PDAs), televisions, radios, computers, and the like. Since the communication between the devices that is required for this purpose is generally undertaken via radio-based methods, such devices contain transmitting and/or receiving units for radio connections. An important constituent of these transmitting and receiving units is the antenna system, by means of which the radio signals are received and/or transmitted.

It is usual to give antenna systems a flat design, allowing an antenna system to be accommodated in the housing of an electrical device and thus protect it from external mechanical effects. As well as the flat antenna unit as the antenna itself, an antenna system of this kind typically also comprises a mechanically stable carrier unit to which the antenna unit is fastened.

As is usual in many sectors of consumer electronics, the individual modular systems in electronic devices with antenna systems, too, are joined to one another in such a device by using pressure-sensitive adhesive tapes, which enables rapid final assembly. The same applies to the fastening of an antenna system in an electronic device, the antenna module being accommodated by a mount in the device or by a separate antenna housing.

The mechanically stable carrier unit is generally a thin carrier plate made of a polymeric plastic. The antenna unit is fixed to this plate. The antenna unit used is typically a metallic wire or a metallic foil; in the case of mobile telephones, for instance, metal foils used are sheets of metallic alloys, for example, those of beryllium and copper. Instead of this it is also possible to print the antenna structure directly onto a carrier, using a particulate suspension—in the form of silver colloids, for example.

In order to fix a wire or foil antenna unit to the carrier unit, the two parts are typically joined to one another using an adhesive. For this purpose it is necessary for the particular adhesive used to have a strong adhesive force both to the polymeric carrier unit and to the metallic antenna. In this context, liquid adhesives are frequently employed as the adhesive system, and allow, overall, high bond strengths, provided the antenna unit is also passively fixed. Passive fixing may entail, for instance, mounts in the surface of the carrier unit which are milled into the carrier plate to match the geometrical form of the particular antenna unit used.

A disadvantage of the use of liquid adhesives is that adhesive bonding in this case can be controlled only via the particular volume of liquid adhesive that is applied. As a result, naturally, the maximum possible spatial accuracy with which such joins can be produced, at least as far as the attainable minimum thickness of join is concerned, is very low, and this is a problem particularly in connection with a three-dimensional spatial antenna design that is customary in some cases. A further factor is that the different thicknesses of the bonding layer do not ensure reproducible dielectric properties in the adhesive bond, and hence may influence the transmitting and/or receiving characteristics of the antenna system as a whole, according to the adhesive bond actually obtained in each case. This necessitates an additional final check on the completed antenna systems, with reject rates that are high in some cases.

The selection of the liquid adhesives is confined to those adhesive systems whose constituents—such as base polymers, reactive systems or solvents, for instance—attack the polymeric carrier unit or the metallic antenna structure. Since liquid adhesives of this kind contain solvents, which have to be removed from the adhesive during the drying of the bond, the time needed for the completion of the antenna system is extended, moreover, by the drying time.

It was an object of the invention, therefore, to provide a method for joining a metallic antenna unit and a carrier unit that does not have these disadvantages and that, in particular, allows a defined, stable adhesive bond with reproducible electrical and dielectric properties within short manufacturing times, allowing high production cycle times to be realized.

This object is achieved in accordance with the invention by a method of the type specified at the outset wherein the adhesive system used is a heat-activatedly bondable and substantially dimensionally stable sheetlike element having an electrical volume resistivity of at least 1012 Ωcm, and in which, in the second joining step, heat activation of the sheetlike element is carried out by heating the sheetlike element through the antenna unit. As a consequence of the use of a sheetlike element rather than liquid adhesives, it is possible to obtain an adhesive bond which has defined and therefore reproducible electrical and dielectric properties. As a result of the high electrical volume resistivity of the sheetlike element used, this adhesive bond is also sufficient to ensure the electrical and dielectric properties of the antenna system that are required for optimum antenna operation, so that particularly compact and thin adhesive bonds are obtained without detriment overall to the transmitting and/or receiving characteristics of the antenna.

As the result of the use of a heat-activatedly bondable sheetlike element having a heat-activatedly bonding adhesive, a defined adhesive bond of high adhesive force can be obtained, as is needed for the use of the antenna system in mobile devices. In this context, the particularly compact and thin adhesive bond specifically enables complete thermal activation of the adhesive in the sheetlike element through the antenna unit, the high thermal conductivity of the metallic antenna material being advantageously utilized. If, in contrast, a less compact sheetlike element were to be used for bonding—for instance, one having a lower volume resistivity, hence necessitating a sheetlike element with a greater thickness in order to achieve the same overall resistance—the sheetlike element overall would be too thick to allow homogeneous heating of the adhesive on the second side face to be carried out via an antenna unit joined to the second side face, in a sufficiently short time.

Only as a consequence of this specific design of the method, therefore, is it possible to avoid a procedure that takes longer and uses more apparatus for the bonding of the polymeric carrier unit to the antenna unit by means of the sheetlike element, since there is no need to add thermal energy to the adhesive via the side of the sheetlike element that is to be bonded, but only via the side that is already bonded. Consequently, all of the individual features of the above method contribute in a substantial way to the effect obtained, without any possibility of leaving out a single one of them.

It is of advantage if the first joining step is carried out at a first joining temperature and the second joining step at a second joining temperature, the second joining temperature being at least as high as the first joining temperature. It is particularly advantageous in this context if the second joining temperature is not only the same as the first joining temperature, but is instead higher than the latter.

This choice of temperature initially ensures that in the second joining step an adhesive join with high adhesive force can be produced, since the heat-activatedly bonding adhesive disposed on the second side face of the sheetlike element is not fully thermally activated in the first joining step, and hence is still available for the second joining step, this being particularly important for reactive adhesive systems. With the higher temperature in the second joining step, therefore, it is possible to achieve a maximum adhesive force, since this ensures that in the first joining step only the first join between the antenna unit and the sheetlike element is made, with a high adhesive force, without activation at this stage of the adhesive disposed on the second side face of the sheetlike element. A consequence of this in turn is that the adhesive joins produced in the first and second joining steps both each have the maximum possible adhesive force, without any detriment to the adhesive action of the adhesive on the second side face that is achieved in the second joining step, as a consequence of premature thermal activation in the first joining step.

The method is particularly suitable, furthermore, when, after the contacting of the antenna element and the carrier unit, and at the same time before the second joining step, the antenna element is joined preliminarily to the carrier unit, forming a weak join between the antenna element and the carrier unit. As a result of such gentle fixing, which is produced before the antenna element and the carrier unit are ultimately joined to one another in the second joining step, the antenna element and the carrier unit are brought into a defined disposition relative to one another, but one which can still be corrected if need be. If no correction is necessary, this prefixed spatial disposition is retained until the ultimate joining of the two parts, and so slipping of the parts relative to one another is prevented.

Such fixing of the parts relative to one another prior to actual joining may advantageously likewise be obtained if the first joining step is already a preliminary joining of the antenna unit to the sheetlike element, forming a weak join between the antenna unit and the sheetlike element. In this way too, slipping of the antenna unit relative to the sheetlike element is prevented, and this is particularly important when, for instance, the antenna unit has a particular shape and the sheetlike element, in the form of a diecut which has already been cut accordingly, is to be given a positionally accurate join to the antenna unit, since in this case slipping would lead to a reduction in the area of overlap and hence a reduction in the overall adhesive force obtained for the join. Moreover, the configuration of the first joining step as preliminary joining is sensible, since in this way, in the second joining step, it is possible to reduce the time for which the system is exposed to particularly high temperatures, and so, as a result, the severe softening or the bubbling that is possible with reactive adhesive systems are countered.

The sheetlike element, accordingly, can be used and adhesively bonded in the form of a prefabricated diecut. Instead of this, however, it is likewise favorable if the durable assembly comprising the carrier unit and the antenna element is punched into the desired shape only after the second joining step. In this way, the parts to be joined need not be aligned exactly relative to one another prior to adhesive bonding in the first and second joining steps, and so the time needed for the manufacture of an element can be reduced. This is then done, however, at the expense of increased trim waste, and consequently this method is carried out in practice when the trim waste is subsequently reprocessed in a recycling system.

A further object of the invention was to provide a heat-activatedly bondable sheetlike element comprising at least one heat-activatedly bonding adhesive, and adapted for durable joining of a metallic antenna unit to a carrier unit, where, for the joining of the sheetlike element to the carrier unit, said element is heated, for the purpose of activating the adhesive, through the antenna unit joined to the sheetlike element beforehand. This object has been achieved by means of a sheetlike element which perpendicular to the principal extent, in other words to the main orientation surface, has an electrical volume resistivity of at least 1012 Ωcm, preferably of 1013 Ωcm, more preferably of 1014 Ωcm. This embodiment ensures that the sheetlike element on the one hand is thin enough, so that the adhesive is activated homogeneously on thermal activation, and on the other hand, at the same time, has sufficient electrical and dielectric properties, thus avoiding an overall deterioration in the transmitting and/or receiving characteristics of the antenna.

It is particularly favorable here if the adhesive has a fraction of free halogens of less than 900 ppm, more particularly chloride and bromide, and preferably a total halogen content of less than 300 ppm and more particularly of less than 100 ppm. In this way it is possible to avoid a corrosive effect of the sheetlike element on the metallic antenna material in the long term as well, and hence to ensure consistent transmitting and/or receiving characteristics on the part of the antenna unit. A corrosive effect of this kind is a problem particularly in the case of prolonged exposure times and also at relatively high temperatures, of the kind that may be used for heat activation.

A further object of the present invention was to obtain durable joining of a metallic antenna unit and a carrier unit in a method in which the time needed for the production of the assembly is kept as short as possible. This can be realized in accordance with the invention through use of the above-described heat-activatedly bondable sheetlike element.

Accordingly, the invention ought to provide an antenna element which can be produced with little consumption of time, and also an antenna system featuring such an antenna element. This has likewise been realized utilizing the sheetlike element of the invention in the method of the invention.

The actual antenna for receiving or transmitting electromagnetic waves is formed by the antenna unit. This antenna unit may be fabricated entirely or at least partly of all customary materials that are suitable for antenna structures and that are at least substantially metallically conducting (referred to below as “metallic”)—for example, of aluminum, of silver, of gold, of copper, of stainless steel or of alloys such as brass, bronzes or those of copper and beryllium. For the purposes of this invention, metallic antenna units of this kind likewise include those produced from other suitable components or materials, more particularly those comprising electronically conducting materials such as, for instance, conductive polymers or the like. Metallic materials of this kind may also have been doped with foreign atoms or foreign ions in order to produce a specific optimization in the electrical properties of the antenna unit; it is possible, moreover, to coat the antenna units superficially to protect against corrosion, such as with precious metals such as gold or silver or with metals for which a passivation coat is formed on the surface, such as aluminum. In this case it is advantageous for the metal surface not be entirely smooth but instead to possess a microroughness, in order thus to increase the adhesion of an adhesive to the antenna.

The size and geometry of these antennas is guided by the particular applications, such as the frequency bands within which data transmission takes place; in principle, the method of the invention can be applied to all known geometries and structures, such as to dipole antennas or to antenna coils. It is usual for the antenna to have a flat structure, in the form, for instance, of an embossed metal sheet, of a specially shaped metal layer applied to a support film, or the like. One of the factors governing the specific embodiment is the electronic device in which the antenna system is to be used.

The antenna element in the present instance is considered to be the assembly, comprising at least one antenna unit and at least one heat-activatedly bondable sheetlike element, that is produced in the course of the manufacture of the antenna system. An antenna element in this context may also comprise two or more antenna units, joined to one sheetlike element or to two or more sheetlike elements. Similarly, an antenna element may also have two or more sheetlike elements each joined to it or even to two or more antenna elements.

An antenna system is an assembly comprising an antenna element and a carrier unit, which are joined via the heat-activatedly bondable sheetlike element. This likewise embraces those antenna systems in which two or more antenna elements are disposed on one carrier unit. For reasons of stability it may be sensible for each antenna element to be fastened only to one single carrier unit, and not to two or more.

By a carrier unit is meant any element which can be fixed as a carrier to an element to be protected, thus providing the element to be protected with at least partial protection from adverse mechanical events, by virtue of the strength of the carrier unit. With regard to its electrical and dielectric properties, a carrier unit must be oriented to use as a carrier for an antenna unit. Furthermore, it is necessary for the material of the carrier unit, at the temperature required for the activation of the sheetlike element, to be sufficiently chemically stable and also dimensionally stable, so as to be able to afford mechanical protection even under such conditions. Serving as carrier unit, typically, are relatively thick sheets and plates of inorganic and/or polymeric materials. Instead, of course, it is also possible to use shaped bodies which serve simultaneously as a housing or encapsulation for the antenna unit.

The carrier unit is joined to the antenna unit via an adhesive system which has at least two side faces, a first side face and a second side face. An adhesive system is considered to be any three-dimensional structure that is suitable for joining two bodies or regions of a body to one another with formation of an adhesive bond. For this purpose it is necessary for the adhesive system to comprise at least one adhesive, which is substantially dimensionally stable within the adhesive bond. This does not rule out the adhesives being originally liquid, and becoming solid only after a chemical reaction or after removal of the solvent.

In accordance with the invention the adhesive system is a heat-activatedly bondable sheetlike element of dimensionally stable design. Sheetlike elements are considered to be all customary sheetlike structures which allow adhesive bonding. They may differ in their embodiment, and in particular may be flexible, in the form for example of a tape, label or film. Heat-activatedly bondable sheetlike elements are sheetlike elements which are bonded hot and which, after cooling, afford a mechanically robust join to the adhesion base (substrate). For this purpose, the heat-activatedly bondable sheetlike elements are provided on both sides with heat-activatedly bonding adhesives. Accordingly, the simplest construction of a heat-activatedly bondable sheetlike element can be realized in the form of a carrierless sheetlike element whose adhesives are identical on both sides, so that the sheetlike element is composed overall only of a single layer of adhesive.

A dimensionally stable element is any element of substantially self-supporting design which has internal—possibly elastic—forces of resilience that counter deformation due to light to moderate loads, and which, accordingly, even under mechanical exposure, does not lose its shape—or, if so, only to a minor extent.

In the present case, the sheetlike element has a first side face and a second side face, which are disposed parallel to its principal extent. Provided on each of the side faces of the sheetlike element is an adhesive, as a substantially two-dimensional adhesive layer. The adhesive on the first side face (first adhesive) and the adhesive on the second side face (second adhesive) may be identical or else differ from one another. The adhesives, advantageously, are different, being differently embodied in accordance with the specific nature of the substrate. For this purpose, for example, the first side face, joined to the antenna unit, may carry an adhesive which develops a particularly high adhesive force with the metallic material of the antenna unit, while the second side face, joined to the carrier unit, may carry an adhesive which develops a particularly high adhesive force with the polymer of the carrier unit.

A sheetlike element of this kind may be of carrierless design, in order to allow the realization of particularly thin constructions (in the form of an adhesive transfer tape, for instance), or else may have a carrier, in order to give the sheetlike element a greater mechanical stability. A carrier of this kind may be composed of all of the materials that are familiar to the skilled person, such as, for example, of polymers such as polyesters, polyethylene, polypropylene, including modified polypropylene such as, for instance, biaxially oriented polypropylene (BOPP), polyamide, polyimide or polyethylene terephthalate, or of natural materials; these may take the form of woven, knitted, scrim or nonwoven fabrics, papers, foams, films, and the like, or else combinations thereof, such as laminates or woven films.

As first and second adhesives it is possible in principle to use all customary and suitable heat-activatedly bonding adhesives. Heat-activatedly bonding adhesives are those adhesives which have no intrinsic tack at room temperature (and differ from conventional pressure-sensitive adhesives), but instead become pressure-sensitively tacky only under temperature exposure and optional pressure, and, after bonding and cooling, through the solidification of the adhesive, develop a high adhesive force. This likewise includes heat-activatedly bonding adhesives which are pressure-sensitively tacky at room temperature. Depending on application temperature, these heat-activatedly bonding adhesives have different static glass transition temperatures Tg,A or melting points Tm,A.

Heat-activatedly bonding adhesives can be ordered in principle into two categories: thermoplastic heat-activatedly bonding adhesives, and reactive heat-activatedly bonding adhesives. Thermoplastic adhesives are based on polymers which soften reversibly on heating and solidify again in the course of cooling. Reactive heat-activatedly bonding adhesives, in contrast, comprise elastic components and reactive components, the so-called “reactive resins”, in which the heating initiates a crosslinking process which, after the end of the crosslinking reaction, ensures a durable, stable join even under pressure. In addition there also exist heat-activatedly bonding adhesives which can be assigned to both categories, and hence which comprise both thermoplastic components and reactive components.

Described below, purely by way of example, are certain typical systems of heat-activatedly bonding adhesives which have proven particularly advantageous in connection with the present invention, these being those based on thermoplastic materials, polyolefins, and acrylic acid derivatives, and on elastomers with reactive resins. In these systems, a polymer or a few polymers, as base polymers, define the fundamental properties of the adhesive, and, in addition, a change in the respective properties can be achieved through inclusion of further polymers and/or additives.

A heat-activatedly bonding adhesive may be embodied, for instance, on the basis of thermoplastic materials. Thermoplastic materials which can be used are all suitable thermoplastics. Polymers of this kind typically possess softening ranges which lie within a temperature range between 45° C. and 205° C. Sensibly in this case the polymer is tailored if desired to the carrier film, in such a way, for instance, that the softening range of the material of the carrier film is situated at higher temperatures than the softening range of the adhesive. By softening temperature is meant a glass transition temperature for amorphous systems, and a melting temperature in the case of semicrystalline polymers. The temperatures stated here correspond to those obtained from quasi-steady-state experiments such as, for example, by means of dynamic scanning calorimetry (DSC).

Use may be made, for example, of polyacrylate-based or polymethacrylate-based heat-activatedly bonding adhesives. As the main constituent of such adhesives it is possible to use all suitable polymers which comprise units of acrylic acid derivatives, more particularly acrylic esters, preferably homopolymers and copolymers with 70% to 100% by weight of acrylic acid compounds and/or methacrylic acid compounds of the general formula CH2=C(R1)(COOR2), where R1 represents a radical selected from the group encompassing H and CH3, and R2 represents a radical selected from the group encompassing H and alkyl chains having 1 to 30 C atoms.

As monomers for this purpose it is possible more particularly to use acrylic monomers which comprise acrylic and methacrylic esters with alkyl groups of 4 to 14 C atoms. Specific examples, without wishing to be restricted by this enumeration, are methyl acrylate, methyl methacrylate, ethyl acrylate, ethyl methacrylate, propyl acrylate, propyl methacrylate, n-butyl acrylate, n-butyl methacrylate, n-pentyl acrylate, n-hexyl acrylate, n-hexyl methacrylate, n-heptyl acrylate, n-octyl acrylate, n-nonyl acrylate, lauryl acrylate, stearyl acrylate, stearyl methacrylate, behenyl acrylate, and also their branched isomers, for instance 2-ethylhexyl acrylate. Other substances which may likewise be added to these monomers in small amounts are cyclohexyl methacrylates, isobornyl acrylates or isobornyl methacrylates.

It has proven favorable in this context if, during the preparation of these polymers, not more than 30% by weight of olefinically unsaturated monomers with functional groups are added to the (meth)acrylate monomers.

As olefinically unsaturated monomers of this kind it is possible to use different classes of compound. Thus, for example, acrylic monomers of the general formula CH2=C(R3)(COOR4) may be used, where R3 represents a radical selected from the group encompassing H and CH3, and OR2 represents or contains a functional group which permits subsequent crosslinking of the adhesive under irradiation with ultraviolet light (UV), and which, for instance, preferably possesses an H-donor effect.

Examples of the olefinically unsaturated monomers are hydroxyethyl acrylate, hydroxypropyl acrylate, hydroxyethyl methacrylate, hydroxypropyl methacrylate, allyl alcohol, maleic anhydride, itaconic anhydride, itaconic acid, acrylamide, glyceridyl methacrylate, benzyl acrylate, benzyl methacrylate, phenyl acrylate, phenyl methacrylate, t-butylphenyl acrylate, t-butylphenyl methacrylate, phenoxyethyl acrylate, phenoxyethyl methacrylate, 2-butoxyethyl methacrylate, 2-butoxyethyl acrylate, dimethylaminoethyl methacrylate, dim ethylaminoethyl acrylate, diethylaminoethyl methacrylate, diethylaminoethyl acrylate, cyanoethyl methacrylate, cyanoethyl acrylate, glyceryl methacrylate, 6-hydroxyhexyl methacrylate, N-tert-butylacrylamide, N-methylolmethacrylamide, N-(butoxy-methyl)methacrylamide, N-methylolacrylamide, N-(ethoxymethyl)acrylamide, N-isopropylacrylamide, vinylacetic acid, tetrahydrofurfuryl acrylate, β-acryloyl-oxypropionic acid, fumaric acid, crotonic acid, aconitic acid, dimethylacrylic acid, this enumeration not being exhaustive.

Moreover, as olefinically unsaturated monomers it is also possible to use aromatic vinyl compounds, the aromatic nuclei being composed typically of C4 to C18 and also being able to contain heteroatoms. Examples thereof are styrene, 4-vinylpyridine, N-vinylphthalimide, methylstyrene, 3,4-dimethoxystyrene, 4-vinylbenzoic acid, this enumeration likewise not being exhaustive.

For the polymerization the monomers are selected in such as way that the resultant bondable polymers can be used as a heat-activatedly bonding adhesive. Specific control over the glass transition temperature can be exerted for this purpose, for instance, via the composition of the monomer mixture on which the polymerization is based.

In order to achieve a polymer glass transition temperature Tg,A of advantageously more than 30° C. for heat-activatedly bonding adhesives, the monomers are selected, for instance, in such a way, and the quantitative composition of the monomer mixture is selected in such a way, that the desired Tg,A value for the polymer is given, in accordance with equation (E1), in analogy to the equation presented by Fox (cf. T. G. Fox, Bull. Am. Phys. Soc. 1 (1956) 123), as follows:

$$\frac{1}{{T}_{g}} = {\sum }_{n} \frac{{w}_{n}}{{T}_{g , n}} . \qquad ( E 1 )$$

In this equation, n represents the serial number of the monomers used, wₙ the mass fraction of the respective monomer n (in % by weight), and T_{g,n} the respective glass transition temperature of the homopolymer of each monomer n (in K).

Polyolefins have proven to be particularly advantageous thermoplastic materials, especially poly-α-olefins having a softening point of more than 40° C., or, for a poly-α-olefin layer on a coextruded temporary carrier, of more than 45° C. Adhesives based on such polyolefins frequently have static glass transition temperatures T_{g,A} or melting points T_{m,A} in a range from 75° C. to 180° C.

Through use of additives it is possible, in thermoplastic systems of this kind, to modify the adhesive force in a specific way, for instance by adding polyimine copolymers or polyvinyl acetate copolymers as additives to boost adhesive force. In this case, sensibly, the thermoplastic polymer is tailored to the carrier film, in such a way, for instance, that the softening range of the carrier film material is situated at higher temperatures than the softening range of the adhesive.

In order to set the static glass transition temperature Tg,A and/or the melting point Tm,A in a specific way in accordance with the particular profile of requirements, the monomers used and their amounts are preferably selected such that, for the polymer prepared from these monomers, the desired temperature is produced in accordance with the equation E1, proposed in analogy to that of Fox.

For practical reasons it is usually sensible further to restrict the static glass transition temperature Tg,A or the melting point Tm,A of the heat-activatedly bonding adhesive in order to be able to prevent thermoplastic softening of the adhesive tape, prior to use, at just an increased ambient temperature, with the adhesive tape then being no longer able to be unwound.

In order to be able to set the optimum temperature range for the thermal activation of such an adhesive, the molecular weight, and also the fraction of the individual comonomers, is modified specifically. For low static glass transition temperatures Tg,A or melting points Tm,A, for instance, polymers with a medium or low molecular weight can be used, or low and high molecular weight polymers can be blended with one another.

Hence, for example, it is possible to use polyethenes, polypropenes, polybutenes, polyhexenes or copolymers of one or more of these substances. In that case, polyethylene and copolymers with polyethylene may be applied, for example, as aqueous dispersions. The blend used in each case will be selected in accordance with the desired profile of requirements, according to the target static glass transition temperature Tg,A or melting point Tm.A of the heat-activatedly bonding adhesive.

Available from the company Degussa under the tradename Vestoplast™ are various heat-activatable poly-α-olefins. For instance, polypropene-rich products are offered under the designations Vestoplast™ 703, 704, 708, 750, 751, 792, 828, 888, and 891. They possess melting points Tm,A from a range from 99° C. to 162° C. Polybutene-rich products are on the market under the designations Vestoplast™ 308, 408, 508, 520, and 608. They possess melting points Tm,A from a range from 84° C. to 157° C.

Further examples of heat-activatedly bonding adhesives are described in the patents U.S. Pat. No. 3,326,741, U.S. Pat. No. 3,639,500, U.S. Pat. No. 4,404,246, U.S. Pat. No. 4,452,955, U.S. Pat. No. 4,404,345, U.S. Pat. No. 4,545,843, U.S. Pat. No. 4,880,683, and U.S. Pat. No. 5,593,759, in which, moreover, references to further such adhesives may be found.

A heat-activatedly bonding adhesive may also be embodied on the basis of elastomeric base polymers and at least one reactive resin. As elastomeric base polymer it is possible to use all suitable elastomeric polymers, synthetic rubbers being an example. Synthetic rubbers contemplated include all customary synthetic rubber systems, for instance those based on polyvinylbutyral, polyvinylformal, nitrile rubbers, nitrile-butadiene rubbers, hydrogenated nitrile-butadiene rubbers, polyacrylate rubbers, ethylene-propylene-diene rubbers, methyl-vinyl-silicone rubbers, butyl rubbers or styrene-butadiene rubbers. The synthetic rubbers are advantageously selected such that they have at least a softening temperature or glass transition temperature from a temperature range from −80° C. to 0° C. Where the synthetic rubbers are block copolymers composed of two or more polymer blocks, then, furthermore, there may also be two or more softening or glass transition temperatures (corresponding overall to the number of different polymer blocks in the block copolymer).

Commercial examples of nitrile-butadiene rubbers are for instance Europrene™ from Eni Chem, or Krynac™ from Bayer, or Breon™ and Nipol N™ from Zeon. Polyvinylformals may be obtained, for instance, as Formvar™ from Ladd Research. Polyvinylbutyrals are available as Butvar™ from Solucia, as Pioloform™ from Wacker, and as Mowital™ from Kuraray. As hydrogenated nitrile-butadiene rubbers, for example, the products Therban™ from Bayer and Zetpol™ from Zeon are available. Polyacrylate rubbers are on the market, for example, as Nipol AR™ from Zeon. Ethylene-propylene-diene rubbers can be acquired, for example, as Keltan™ from DSM, as Vistalon™ from Exxon Mobile, and as Buna EP™ from Bayer. Methyl-vinyl-silicone rubbers are available, for instance, as Silastic™ from Dow Corning and as Silopren™ from GE Silicones. Butyl rubbers are available, for instance, as Esso Butyl™ from Exxon Mobile. Styrene-butadiene rubbers used may be, for instance, Buna S™ from Bayer, Europrene™ from Eni Chem, and Polysar S™ from Bayer.

Furthermore, it is also possible to use mixtures with thermoplastics and elastomers. Typical thermoplastic materials used for this purpose are selected from the group of the following polymers: polyurethanes, polystyrene, acrylonitrile-butadiene-styrene terpolymers, polyesters, polyoxymethylenes, polybutylene terephthalates, polycarbonates, polyamides, ethylene-vinyl acetates, polyvinyl acetates, polyimides, polyethers, poly(meth)acrylates, copolyamides, copolyesters, and polyolefins, such as polyethylene, polypropylene, polybutene or polyisobutene, for example. The enumeration possesses no claim to completeness. These thermoplastic materials frequently possess a softening or glass transition temperature of between 60° C. and 125° C.

In order to optimize the technical adhesive properties and the activation temperature, in other words the temperature at which the adhesive, under thermal activation, becomes pressure-sensitively tacky, it is possible, as an option, to add reactive resins or resins which boost adhesive force. The proportion of such resins is between 5% and 75% by weight, based on the mass of the overall mixture of elastomer and resins.

Thus the first adhesive may comprise a reactive resin which is capable of crosslinking with itself, with other reactive resins and/or with another component of the adhesive, such as with the base polymer. Reactive resins in an adhesive influence the technical adhesive properties of that adhesive as a consequence of chemical reactions. As reactive resins it is possible in the present context to use all customary reactive resins. More particularly as reactive resins it is possible to use epoxy resins, novolac resins, melamine resins, phenolic resins, terpene-phenolic resins and/or polyisocyanate-based resins.

As epoxy resins it is possible to use all suitable epoxy resins known to the skilled person, more particularly polymeric epoxy resins having an average molecular weight Mw from a range from 100 g/mol to not more than 10 000 g/mol, such as glycidyl esters and aliphatic epoxy resins. Preferred commercial examples of these are Araldite™ 6010, CY-281™, ECN™ 1273, ECN™ 1280, MY 720, RD-2 from Ciba Geigy, DER™ 331, DER™ 732, DER™ 736, DEN™ 432, DEN™ 438, DEN™ 485 from Dow Chemical, Epon™ 812, 825, 826, 828, 830, 834, 836, 871, 872, 1001, 1004, 1031, etc., from Shell Chemical, and HPT™ 1071, HPT™ 1079, likewise from Shell Chemical. Examples of commercial aliphatic epoxy resins are vinylcyclohexane dioxides such as ERL-4206, ERL-4221, ERL-4201, ERL-4289, and ERL-0400 from Union Carbide Corp.

As novolac resins it is possible to use all suitable novolac resins known to the skilled person, examples being Epi-Rez™ 5132 from Celanese, ESCN-001™ from Sumitomo Chemical, CY-281™ from Ciba Geigy, DEN™ 431, DEN™ 438, Quatrex™ 5010 from Dow Chemical, RE 305S from Nippon Kayaku, Epiclon™ N673 from DaiNippon Ink Chemistry, and Epicote™ 152 from Shell Chemical.

As melamine resins it is possible to use all suitable melamine resins known to the skilled person, examples being Cymel™ 327 and 323 from Cytec.

As phenolic resins it is possible to use all suitable phenolic resins known to the skilled person, examples being YP 50 from Toto Kasei, PKHC™ from Union Carbide Corp., and BKR™ 2620 from Showa Union Gosei Corp. In addition as reactive resins it is also possible to use phenolic resole resins, inter alia also in combination with other phenolic resins.

As terpene-phenolic resins it is possible to use all suitable terpene-phenolic resins that are known to the skilled person, an example being NIREZ™ 2019 from Arizona Chemical.

As polyisocyanate-based resins it is possible to use all suitable polyisocyanate-based resins known to the skilled person, examples being Coronate™ L from Nippon Polyurethan Ind., Desmodur™ N3300 and Mondur™ 489 from Bayer.

In order to accelerate the reaction between the two components, the adhesive may optionally further comprise crosslinkers and accelerants as well. Suitable accelerants are all suitable accelerants that are known to the skilled person, such as imidazoles, available commercially as 2M7, 2E4MN, 2PZ-CN, 2PZ-CNS, P0505 and L07N from Shikoku Chem. Corp. and as Curezol 2MZ from Air Products, and also amines, especially tertiary amines. Suitable crosslinkers are all suitable crosslinkers known to the skilled person, an example being hexamethylenetetramine (HMTA).

Additionally, the adhesive may optionally also comprise further constituents, examples being plasticizers, fillers, nucleators, expandants, additives which boost adhesive force, and thermoplastic additives, compounding agents and/or aging inhibitors.

As plasticizers it is possible to use all suitable plasticizers known to the skilled person, examples being those based on polyglycol ethers, polyethylene oxides, phosphate esters, aliphatic carboxylic esters, and benzoic esters, aromatic carboxylic esters, high molecular weight diols, sulfonamides, and adipic esters.

As fillers it is possible to use all suitable fillers known to the skilled person, examples being fibers, carbon black, zinc oxide, titanium dioxide, chalk, silica, silicates, solid spheres, hollow spheres or microspheres of glass or other materials.

As aging inhibitors it is possible to use all suitable aging inhibitors known to the skilled person, examples being those based on primary and secondary antioxidants or light stabilizers.

As elastic components there is particular interest in synthetic nitrile rubbers, which, by virtue of their high flow viscosity, give the heat-activatedly bonding adhesive a dimensional stability which is especially high even under pressure.

As additives which boost adhesive force it is possible to use all suitable additives known to the skilled person, whose effects include that of boosting the adhesive force (but within the adhesive may also have other functionality as well), examples being polyvinylformal, polyvinylbutyral, polyacrylate rubber, ethylene-propylene-diene rubber, methyl-vinyl-silicone rubber, butyl rubber or styrene-butadiene rubber. Polyvinylformals are available as Formvar™ from Ladd Research. Polyvinylbutyrals are available as Butvar™ from Solucia, as Pioloform™ from Wacker, and as Mowital™ from Kuraray. Polyacrylate rubbers are available as Nipol AR™ from Zeon. Ethylene-propylene-diene rubbers are available as Keltan™ from DSM, as Vistalon™ from Exxon Mobile, and as Buna EP™ from Bayer. Methyl-vinyl-silicone rubbers are available as Silastic™ from Dow Corning and as Silopren™ from GE Silicones. Butyl rubbers are available as Esso Butyl™ from Exxon Mobile. Styrene-butadiene rubbers are available as Buna S™ from Bayer, as Europrene™ from Eni Chem, and as Polysar S™ from Bayer.

As thermoplastic additives it is possible to use all suitable thermoplastics known to the skilled person, examples being thermoplastic materials from the group of polyurethanes, polystyrene, acrylonitrile-butadiene-styrene terpolymers, polyesters, polyoxymethylenes, polybutylene terephthalates, polycarbonates, polyamides, ethylene-vinyl acetates, polyvinyl acetates, polyimides, polyethers, copolyamides, copolyesters, polyacrylates, and polymethacrylates, and also polyolefins such as, for instance, polyethylene, polypropylene, polybutene, and polyisobutene.

Furthermore, optionally, for the purpose of optimizing the technical adhesive properties and the activation range of the adhesive, it is possible to add adhesive force booster resins to the first adhesive and/or to the second adhesive. Adhesive force booster resins which can be used include, without exception, all tackifier resins that are already known and are described in the literature, examples being pinene resins, indene resins, and rosins, their disproportionated, hydrogenated, polymerized and/or esterified derivatives and salts, aliphatic and aromatic hydrocarbon resins, terpene resins and terpene-phenolic resins, and also C5 hydrocarbon resins, C9 hydrocarbon resins, and other hydrocarbon resins. Any desired combinations of these and further resins may be used in order to adjust the properties of the resultant adhesive in accordance with requirements. Generally speaking, it is possible to use any resins that are compatible with (i.e., miscible with or soluble in) the elastomer constituents, more particularly all aliphatic, aromatic or alkylaromatic hydrocarbon resins, hydrocarbon resins based on pure monomers, hydrogenated hydrocarbon resins, functional hydrocarbon resins, and also natural resins; in this context, express reference may be made to the depiction of the state of knowledge in “Handbook of Pressure Sensitive Adhesive Technology” by Donatas Satas (van Nostrand, 1989). Moreover, the adhesive force of the heat-activatedly bondable sheetlike element can be boosted through further specific additization, as for instance by using polyimine copolymers and/or polyvinyl acetate copolymers as adhesive force promoter adjuvants.

It will be appreciated that a heat-activatedly bonding adhesive of this kind, based on elastomeric base polymers with modifying resins, may further comprise additional formulating constituents and/or auxiliaries, in so far as this is necessary or desired in accordance with the particular end use for the specific control of certain properties of the adhesive or of the adhesive bond. Particularly in combination with the reactive systems, a large number of other adjuvants are frequently used, such as resins, filling materials, catalysts, aging inhibitors, and the like.

An important property possessed by the heat-activatedly bondable sheetlike element obtained with these adhesives is an electrical volume resistivity of at least 1012 Ωcm, preferably of 1013 Ωcm, and more preferably of 1014 Ωcm (determined in each case at 25° C.). The volume resistivity refers to the resistance of a body relative to its thickness. It constitutes a characteristic value which provides a directly measurable property of the sheetlike element. In accordance with the invention, such measurement of the volume resistivity can be carried out in accordance with DIN IEC 93. Since the volume resistivity in the present case is relatively high, the sheetlike element is thus at least partly insulating in its behavior.

The size of the volume resistivity is dependent, for each specific heat-activatedly bondable sheetlike element used, on the composition of the adhesive (or adhesives) and also, where appropriate, of the carrier used. Accordingly, for example, the volume resistivity of the sheetlike element overall may be modified through the choice of polymers in the adhesive or a carrier film, for instance by using electrically insulating polymers or—for specialty applications—electrically conducting polymers. Moreover, even nonpolymeric constituents may contribute to the conductivity and to the volume resistivity of the adhesives and of the carrier film, as for instance through the use of ionic adjuvants such as, for example, salts or metallic particles—more particularly those which have a high mobility in the polymer matrix, for instance in the context of diffusion or ion migration. Furthermore, chemical reactions of the constituents of the sheetlike element may need to be considered, such as aging or degradation processes which produce electrically conducting products. Finally, the specific geometric disposition of the individual sections of the sheetlike element may also be important, such as the use of a carrier and the specific embodiment of that carrier, in the form, for example, of a two-dimensionally coherent film or else a perforated film or a nonwoven.

Where the skilled person, from among the multiplicity of different adhesive systems and constructions that are generally available for the sheetlike element, has selected a specific adhesive system and also a sheetlike element construction in accordance with the specific profile of requirements, he or she is aware of a multiplicity of specific measures by means of which the sheetlike element can be adapted in respect of its volume resistivity—for instance, through additional additization or application of a further insulating varnish layer or primer layer between the carrier and the adhesive.

It may make sense, furthermore, to select the composition of the adhesives—at least the composition of the adhesive on the first side face of the sheetlike element—in such a way that it has a fraction of free halogens, more particularly chloride and bromide, of less than 900 ppm, preferably a total halogen content of less than 300 ppm and more particularly of less than 100 ppm. Free halogens are considered on the one hand to be halides and other halogen-containing ions in the adhesive, such as fluoride, chloride, bromide or iodide, for example, and also the corresponding oxygen-containing anions, such as chlorate, perchlorate, and the like, for example, and also, possibly, pseudohalides that are chemically similar to them. On the other hand, however, free halogens are also considered to include all further molecules which in customary aging-related, photochemical or thermal degradation reactions may, directly or indirectly, release at least one of the above-mentioned ions or even molecular/atomic halogens. The fraction of such anions as a proportion of the adhesive is measured, for instance, by means of ion chromatography in accordance with EN 14582.

The adhesives set out above, and also other adhesives which, though not comprehensively described here, are nevertheless known to the skilled person, readily, as heat-activatedly bonding adhesives, are applied in conventional processes typically to a temporary carrier, such as to what is called a process liner or a release liner. In accordance with the particular application process, the adhesive may be coated from a solution. For the blending of the base polymer with other constituents such as reactive resins or auxiliaries, for instance, it is possible here to use all known mixing or stirring technologies. Thus, for example, static or dynamic mixing assemblies may be employed to produce a homogeneous mixture. Blending of the base polymer with reactive resins may alternatively be carried out in the melt. For that purpose it is possible to employ kneading devices or twin-screw extruders. Blending takes place preferably with heating, in which case the mixing temperature ought to be significantly lower than the activation temperature for reactive processes in the mixing assembly, such as for reaction of the epoxy resins.

For application of the adhesive from the melt, the solvent can be stripped off under reduced pressure in a concentrating extruder, for which purpose it is possible, for example, to use single-screw or twin-screw extruders, which preferably distill off the solvent in the same vacuum stage or in different vacuum stages, and possess a feed preheater. Advantageously, the fraction of solvent remaining in the adhesive is less than 1% by weight or, even, less than 0.5% by weight.

In this way a sheetlike element is obtained which is furnished on both sides with identical or different heat-activatedly bonding adhesives. For the purpose of ease of handling of the sheetlike element during storage and processing, the first side face and/or second side face of the sheetlike element may additionally be covered with a temporary carrier (for instance what is called a release liner), which is peeled off immediately prior to the bonding of this side face. As temporary carriers it is possible to use all liners known to the skilled person, such as release sheets and release varnishes. Release sheets are, for example, adhesion-reduced papers and also films based on polyethylene, polypropylene, polyethylene terephthalate, polyethylene naphthalate, polyimide, or mixtures of these materials. Release varnishes are frequently silicone varnishes or fluorinated varnishes for reducing adhesion.

For the implementation of the method of the invention, the first side face of the sheetlike element is contacted with the antenna unit without initially the formation of a complete adhesive bond. Where the method is carried out using a sheetlike element which has a temporary carrier on its first side face, this temporary carrier is peeled off prior to the establishment of contact of the adhesive on the first side face.

In the first joining step, the antenna unit is joined to the first side face of the sheetlike element to form an antenna element; this takes place with thermal activation of the adhesive on the first side face of the sheetlike element. For this purpose it is possible to use all customary and suitable joining methods; it has proved to be favorable to carry out the joining in the form of hot lamination, in which the antenna unit and the sheetlike element are heated to the desired first joining temperature and pressed against one another under pressure. For this purpose it is possible to employ all customary laminator arrangements, examples being those with pressing dies, pressure-contact rolls or pressure rolls.

The first joining step can be performed such that the antenna unit is firmly and durably joined to the sheetlike element. Instead of this, however, the first joining step can also be carried out by preliminarily joining the antenna unit to the sheetlike element (for instance, as a prelaminating operation at relatively low temperatures, so that the adhesive on the first side face is not fully activated), forming a weak joint between the antenna unit and the sheetlike element. A weak join in the present context is considered to be any join in which the adhesive does not adhere durably and firmly to the antenna unit, but instead could if desired be detached from it again.

With a procedure of this kind, an ultimate, firm and durable, adhesive bond is obtained not until the second joining step, and the same applies to the adhesive on the first side face. In this way, in the first joining step, low first joining temperatures are sufficient. Accordingly, for example, identical adhesives can be used on both side faces of the sheetlike element, since it is possible in this way to activate only a small part of the adhesive on the second side face in the first joining step.

The heating of the adhesive may take place in a separate heating section or else via a heating means integrated into the rolls. For this purpose the sheetlike element and also, where appropriate, the antenna unit contacted therewith is or are conveyed past a heating means or between two or more heating means. The heating means heats the adhesive on the first side face to the target first joining temperature, in order to activate it. Heating of the sheetlike element can be achieved by the heating means heating the sheetlike element via its first side face or else via its second side face, in other words through the sheetlike element. In the latter case, the thermal conductivity of the sheetlike element means that the adhesive, so to speak, is heated as well on the first side face. Generally speaking, and particularly when using heated laminating rolls, the surface of the rolls should be of temperature-resistant design, having—for instance—a metallic surface or temperature-resistant rubberizing.

It is sensible here if the adhesives on the two side faces of the heat-activatedly bondable sheetlike element are selected such that the second activation temperature, needed to activate the adhesive on the second side face, is higher than the first activation temperature, needed to activate the adhesive on the first side face, and such that, at the same time, the first joining temperature is selected to be at least as high as the first activation temperature, but lower than the second activation temperature.

Thus, for example, in a production method of the invention, the heat-activatable sheetlike element on a release liner can be pressed first, in a first joining step, onto the antenna unit, such as by means of an unheated pair of rolls at room temperature, and then joined by means of the heated rollers of a hot-roller laminator, with introduction of heat and pressure, to the antenna unit. Pressure transfer may take place usually through the use of one or more laminating rolls, preferably having a rubberized surface.

For a hot laminating operation of this kind it is possible—taking account of the activation temperature of the heat-activatedly bonding adhesives—to control the strength of the adhesive bond via the rate of advance, the pressure exerted, and the first joining temperature. Typical operating conditions when using a hot roll laminator are, for instance, an application pressure from a range from 1 bar to 20 bar. The first processing temperature here is selected in general from a temperature range from 50° C. to 170° C., depending on the activation temperature of the heat-activatedly bonding adhesive. Moreover, two or more hot roller laminators may also be combined. Typical travel speeds are between 0.5 m/min and 50 m/min or even only between 2 m/min and 10 m/min. The heated rollers of the roller laminator may be heated from the inside or heated by an external heat source, electrically or by means of infrared lamps, for example.

Where an adhesive is employed which has a temporary carrier on the second side face, that temporary carrier is peeled from the adhesive on the second side face after the first joining step.

Afterward, the second side face of the sheetlike element joined to the antenna unit is contacted with the carrier unit, without formation initially of a complete adhesive bond. After contact has been produced, sheetlike element and carrier unit may be preliminarily joined as a prefixed structure, forming a weak join between the antenna element and the carrier unit. This prevents the two parts slipping relative to one another before they have been ultimately, durably adhesively bonded to one another.

In the second joining step, the carrier unit is durably and firmly joined to the second side face of the adhesive system, to produce an antenna system; this takes place likewise with thermal activation, for which purpose the adhesive on the second side face of the sheetlike element must be heated. For this joining step as well it is possible to use all customary and suitable joining processes; these may be identical to or different from the joining process used for the first joining step. With the second joining step as well it has proved to be favorable to carry out the joining by hot lamination. In that case the antenna element with the sheetlike element is heated to the desired second joining temperature and pressed under pressure onto the carrier unit. Here again, in principle, it is possible to employ all customary laminator arrangements, examples being those with pressing dies, pressure-contact rolls or pressure rolls. The apparatus-related measures used in the second joining step can be selected as for the first joining step or differently therefrom.

In accordance with the invention the adhesive is heated here by heating the adhesive on the second side face of the sheetlike element not directly but instead through the metallic antenna unit—that is, the corresponding heating means heat the antenna unit and, as a consequence of the high thermal conductivity of the antenna unit, the adhesive on the second side face of the sheetlike element is heated to the second joining temperature via the antenna unit and through the first adhesive and, where appropriate, the carrier. The second joining temperature is at least as high as the second activation temperature, preferably higher than the first activation temperature of the first adhesive. Preferably, moreover, the second joining temperature is equal to or even higher than the first joining temperature, in order to minimize the fraction of adhesive on the second side face that has already been thermally activated in the first joining step, and hence to allow the maximum possible adhesive force of the sheetlike element overall. Heating means used here may likewise be devices which are in thermal contact with the antenna unit, such as heating rollers, or else contactless heating means, as in the case, for instance, of the heating of the metallic antenna unit by means of inductively generated eddy currents (induction heating) or by means of infrared lamps.

After the antenna element has been joined to the carrier unit to produce the antenna system, it may additionally be necessary for the antenna system that is to be installed in the electronic device to be brought into a desired shape. For that purpose it is possible to employ all customary shaping methods, such as rolling (in the case of a carrier unit embodied as a film) or cutting of the antenna system to size. In the latter case it is usual, for instance, to punch the desired antenna structure from a sheetlike composite workpiece and so to obtain an antenna system in the desired shape. Instead, however, the individual components can also be brought into the desired shape prior to joining. Thus, for instance, a metal antenna plate in web form may first be cut into the desired antenna shape and joined to a complementary punching of the sheetlike element. Furthermore, the carrier unit may be joined to the antenna element when said unit is already in the ultimately desired shape. For the installation of the antenna system into an electronic device all that is then needed is for the antenna element to be fastened to the device and joined conductingly to its receiving and/or transmitting electronics.

In the method of the invention, therefore, a sheetlike element is obtained which can be used for the durable joining of a metallic antenna unit and a carrier unit, enabling a particularly stable and compact join which can be produced in short production times.

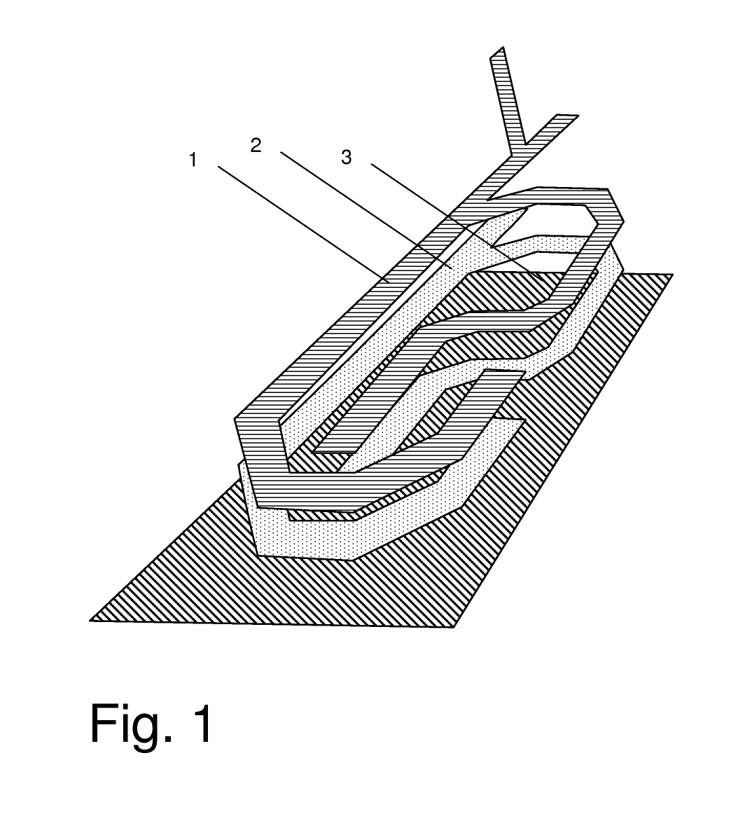

Further advantages and application possibilities will emerge from the working examples, which are to be described in more detail below with reference to the attached drawing. In that drawing, FIG. 1 shows diagrammatically an exploded view of one possible embodiment of the inventive antenna system.

The antenna system shown in FIG. 1 comprises an antenna element which has been brought into the desired form even prior to joining, and which is composed of a preformed sheet 1 of a copper-beryllium alloy as an antenna unit, and of a double-sided adhesive preform 2 as a heat-activatedly bondable sheetlike element. The antenna system further comprises an epoxy resin plate 3 as a stable carrier unit, designed as a rectangular installation plate. In the antenna system the three constituents are joined to one another. The preformed sheet 1 of the antenna element is joined over its full area, overlapping with the epoxy resin plate 3, via the adhesive preform 2. The section of the preform sheet 1 which in the rear zone protrudes beyond the epoxy resin plate 3 serves in this case as a joining means for placing the antenna element into electrically conducting contact with the transmitting and/or receiving electronics of the device.

The suitability of the method of the invention is illustrated below, purely by way of illustration, on the basis of two specific examples, without any intention that the choice of samples investigated should impose a restriction.

Two heat-activatedly bonding adhesives were prepared and were converted to the form of carrierless sheetlike elements. For the first sheetlike element, 50% by weight of a nitrile rubber (Breon N36 C80 from Zeon), 40% by weight of a phenolic-novolac resin (Durez 33040 Rohm and Haas; blended with 8% hexamethylenetetramine), and 10% by weight of a phenolic-resole resin (9610 LW from Bakelite) were prepared as a solution (30%) in methyl ethyl ketone. This was done by mixing the constituents in a kneading device for 20 hours. The resulting adhesive was coated from solution onto a graded temporary carrier film (Glassine Liner from Laufenberg with thickness of 70 μm) and subsequently dried at 100° C. for 10 minutes. The thickness of the adhesive obtained after drying was 100 μm. When the volume resistivity was measured in accordance with DIN IEC 93, the result for this system was a figure of 1.5×1015 Ωcm (carried out at a temperature of 25° C. according to A.2.1 (Wheatstone) with a test voltage of 500 V for a measuring electrode surface area of 5.31 cm2 and an electrode spacing of 0.1 mm). The halide concentrations in the adhesive, determined in accordance with EN 14582, were 452 ppm for chloride and less than 30 ppm for bromide.

For the second sheetlike element, 75% by weight of a copolyester (Griltex 9 E from EMS-Grilltech) were mixed with 25% by weight of a bisphenol A epoxy resin having a softening range around 60° C. (EPR 0191 from Bakelite) in a recording extruder (Haake) at a temperature of 130° C. for 15 minutes at 25 min-1. The resulting adhesive was then rolled out at a processing temperature of 140° C. between two layers of siliconized Glassine release paper, to a thickness totaling 60 μm. When the volume resistivity was measured in accordance with DIN IEC 93, the result for this system was a figure of 6.0×1015 Ωcm (carried out at a temperature of 25° C. according to A.2.1 (Wheatstone) with a test voltage of 500 V for a measuring electrode surface area of 5.31 cm2 and an electrode spacing of 0.1 mm). The halide concentrations in the adhesive, determined in accordance with EN 14582, were less than 30 ppm for chloride and the same for bromide.

The sheetlike elements obtained in this way were contacted with a preshaped antenna unit comprising a copper-beryllium alloy (99.8% Cu and 0.2% Be) and bonded to one another at a first bonding temperature of 130° C. under a low pressure (2 bar) to produce a preliminary join. Thereafter the sheetlike element was adapted by subsequent cutting to the lateral dimensions of the preshaped antenna unit, to produce a shaped antenna element.

The carrier unit used was an antenna body comprising glass fiber-reinforced nylon 6. It was contacted with the antenna unit, heated to the second joining temperature of 150° C. through the antenna unit in a heated roller laminator, and subjected to a pressure of 2 bar via a pressure-contact roller for a pressing time of 10 seconds. The resultant antenna systems were the same in terms of their construction as the antenna systems shown diagrammatically in FIG. 1.

To investigate the mechanical stability of the adhesive bond, the resultant antenna systems were each subjected to two practical tests whose purpose was to investigate the suitability of the antenna systems for typical applications in mobile electronic devices.

In a drop test, the antenna system was dropped from a height of 2 m onto a flat metal surface. The test was carried out at an ambient temperature of 23° C. and additionally at an ambient temperature of −20° C., for which the test specimens in question were equilibrated beforehand to the corresponding temperature, after which ten individual drop trials were conducted with the same test specimen in each case. The result recorded for this test was the maximum number of drop trials in which there had been no parting of any of the adhesive bonds present in the antenna system.

In a long-term climatic cycling test, the antenna system was subjected for the duration of 14 days to a temperature program which was repeated cyclically. In this program, the antenna system was first heated over the course of 1 hour from a temperature of −30° C. to a temperature of 85° C., during which it was subjected to an atmosphere with 85% relative humidity. The antenna system was left under the latter conditions for a period of 10 hours. Thereafter the antenna system was cooled over 1 hour back to a temperature of −30° C. A pass was scored in this test when after 14 days no adhesive bond had undergone complete or partial parting.

For the first sheetlike elements and for the second sheetlike elements, detachment of the individual elements of the antenna system was observed neither in the ten drop trials at temperatures of 23° C. and 20° C., nor in the climatic cycling tests conducted.

The drop test was passed both at low temperatures and at relatively high temperatures without adverse effect on the antenna system. Furthermore, the thermal stresses which occurred during the climatic cycling test, owing to the different expansion coefficients of the plastic carrier, the metal antenna, and the heat-activatedly bondable sheetlike element were accommodated by the heat-activatedly bondable sheetlike element and compensated, in such a way that there was no observed lifting of the antenna from the antenna body. The tests therefore demonstrate that the antenna systems obtained by way of the method of the invention are extraordinarily stable.

1-11. (canceled)

12. A method for producing an antenna system including at least one metallic antenna unit and at least one carrier unit, said method comprising the steps of
contacting the antenna unit with a first side face of an adhesive system,
in a first joining step, joining the antenna unit to the first side face of the adhesive system to form an antenna element,
contacting the resulting antenna element on a second side face of the adhesive system with a carrier unit, and
in a second joining step, durably joining the carrier unit to the second side face of the adhesive system of the antenna element,
wherein the adhesive system provided is a heat-activatedly bondable and substantially dimensionally stable sheet-shaped element having an electrical volume resistivity of at least 10¹² Ωcm, and
in the second joining step, heat activation of the sheet-shaped element is carried out by heating the sheet-shaped element through the antenna unit.

13. The method of claim 12, wherein the first joining step is carried out at a first joining temperature and the second joining step is carried out at a second joining temperature, the second joining temperature being at least as high as the first joining temperature.

14. The method of claim 13, wherein the second joining temperature is higher than the first joining temperature.

15. The method of claim 13, wherein after the contacting of the antenna element and the carrier unit, and before the second joining step, the antenna element is joined preliminarily to the carrier unit, forming a weak joining between the antenna element and the carrier unit.

16. The method of claim 13, wherein the first joining step is a preliminary joining of the antenna unit to the sheet-shaped element, forming a weak join between the antenna unit and the sheet-shaped element.

17. The method of claim 13, wherein the durable assembly comprising the carrier unit and further comprising the step of cutting the antenna element into a desired shape after the second joining step.

18. A heat-activatedly bondable sheet-shaped element for durable joining of a metallic antenna unit to a carrier unit, said sheet-shaped element comprising at least one heat-activatedly bonding adhesive, wherein the sheet-shaped element perpendicular to the principal extent has an electrical volume resistivity of at least 10¹² Ωcm.

19. The sheet-shaped element of claim 18, wherein the adhesive has a fraction of free halogens of less than 900 ppm.

20. A method for using a heat-activatedly bondable sheet-shaped element of claim 18 for durably joining a metallic antenna unit and a carrier unit.

21. An antenna element comprising a metallic antenna unit and a heat-activatedly bondable sheet-shaped element of claim 18.

22. An antenna system comprising an antenna element of claim 21 and a carrier unit.

23. The heat-activatedly bondable sheet-shaped element of claim 18, wherein the sheet-shaped element perpendicular to the principal extent has an electrical volume resistivity of 10¹³ Ωcm.

24. The heat-activatedly bondable sheet-shaped element of claim 18, wherein the sheet-shaped element perpendicular to the principal extent has an electrical volume resistivity of 10¹⁴ Ωcm.

25. The sheet-shaped element of claim 18, wherein the adhesive has a fraction of chloride and bromide, of less than 900 ppm.

26. The sheet-shaped element of claim 18, wherein the adhesive has a fraction of free halogens, having a total halogen content of less than 300 ppm.

27. The sheet-shaped element of claim 18, wherein the adhesive has a fraction of free halogens, having a total halogen content of less than 100 ppm.

28. A method for using of a heat-activatedly bondable sheet-shaped element of claim 18 for durably joining a metallic antenna unit and a carrier unit.

29. A method for using of a heat-activatedly bondable sheet-shaped element of claim 19 for durably joining a metallic antenna unit and a carrier unit.

30. An antenna element comprising a metallic antenna unit and a heat-activatedly bondable sheet-shaped element of claim 19.
